(19) United States
(12) Patent Application Publication
(10) Pub. No.: US 2025/0311344 A1
(43) Pub. Date: Oct. 2, 2025

(54) THERMODYNAMIC STABILIZATION LAYERS FOR OXIDE SEMICONDUCTOR HETEROJUNCTIONS

(71) Applicants: Alliance for Sustainable Energy, LLC, Golden, CO (US); Colorado School of Mines, Golden, CO (US)

(72) Inventors: Marshall Brooks TELLEKAMP, JR., Denver, CO (US); Andriy ZAKUTAYEV, Boulder, CO (US); Kingsley Onyekachi EGBO, Westminster, CO (US); Cheng-Wei LEE, Arvada, CO (US); Vladen STEVANOVIC, Arvada, CO (US)

(21) Appl. No.: 19/095,482

(22) Filed: Mar. 31, 2025

Related U.S. Application Data
(60) Provisional application No. 63/571,833, filed on Mar. 29, 2024.

(51) Int. Cl. H10D 62/82

(52) U.S. Cl. CPC H10D 62/8271

(57) ABSTRACT

Described herein are the insertion of thermodynamic stabilization layers between p- and n-type oxide heterojunction semiconductors that allow for operation and stability at high temperatures, for example, greater than 500° C. The stabilization layer may have a spinel crystal structure and the surrounding layers may be coincidence site lattice matched. An example formulation is n-type Ga₂O₃ and p-type NiO separated by a spinel NiGa₂O₄ stabilization layer.

### CROSS-REFERENCE TO RELATED APPLICATIONS

This application claims priority from U.S. Provisional Patent Application No. 63/571,833, filed on Mar. 29, 2024, the contents of which are incorporated herein by reference in their entirety.

### CONTRACTUAL ORIGIN

This invention was made with government support under Contract No. DE-AC36-08GO28308 awarded by the Department of Energy. The government has certain rights in the invention.

### SUMMARY

Described herein are the insertion of thermodynamic stabilization layers between p- and n-type oxide heterojunction semiconductors that allow for operation and stability at high temperatures, for example, greater than 500° C. The stabilization layer may have a spinel crystal structure and the surrounding layers may be coincidence site lattice matched. An example formulation is n-type Ga₂O₃, p-type NiO separated by a spinel NiGa₂O₄ stabilization layer.

For example, the present application is directed to a p-n heterojunction between n-type Ga₂O₃ and another p-type oxide. In this permutation Ga₂O₃ and NiO form a coincident lattice match along the (100) direction of Ga₂O₃ which is matched to NiO (010), and another coincident site match along the Ga₂O₃(010) which is matched to NiO (110). To prevent thermodynamic intermixing, a layer of NiGa₂O₄ spinel is placed in between NiO and Ga₂O₃, with the same crystallographic orientation as NiO. The layers are crystalline and epitaxially aligned to decrease defects and improve device performance.

β-phase (monoclinic) Ga₂O₃ is a promising material for power electronics and high temperature electronics due to a wide band gap, n-type dopability, oxide chemical resistance, and the availability of scalable bulk substrates. β-Ga₂O₃ is not currently p-type dopable, therefore heterojunctions with p-type oxides are used to form p-n junctions. β-Ga₂O₃ is often matched with NiO, Cr₂O₃, Cu₂O, and other materials. NiO and Ga₂O₃ are not a thermodynamically stable junction—eventually the NiGa₂O₄ spinel will form. NiGa₂O₄ is also a p-type wide gap oxide semiconductor and is thermodynamically stable with both NiO and Ga₂O₃. Therefore, the interface is thermodynamically passivated.

In an aspect, provided is a device comprising: a p-type transition metal oxide layer; an n-type Ga₂O₃ layer; and an XGa₂O₄ layer positioned between the p-type transition metal oxide layer and the n-type Ga₂O₃ layer, wherein X is a transition metal.

In an aspect, provided is a device comprising: a p-type NiO layer; an n-type Ga₂O₃ layer; and an NiGa₂O₄ layer positioned between the p-type transition metal oxide layer and the n-type Ga₂O₃ layer and having a spinel crystal structure.

The p-type transition metal oxide layer may comprise NiO and X may be Ni. The n-type Ga₂O₃ layer may be coincidence site lattice matched along the (100) direction of the Ga₂O₃ layer with the p-type transition metal oxide layer/NiO layer along the (010) direction. The n-type Ga₂O₃ layer may be coincidence site lattice matched along the (010) direction of the Ga₂O₃ layer with the p-type transition metal oxide layer/NiO along the (100) direction.

The XGa₂O₄ layer may have a spinel crystal structure and may be p-type.

The device may have improved thermodynamic stability, for example, at temperatures greater than or equal to 250° C., 400° C., 500° C., or optionally, 550° C. The device may be a p-n heterojunction semiconductor. The XGa₂O₄ layer or NiGa₂O₄ may have a height selected from the range of 1 nm to 10 nm, or about 5 nm.

The n-type Ga₂O₃ layer may be β-Ga₂O₃.

The device may further comprise a Ti layer proximate to the n-type Ga₂O₃ layer and a Ni layer proximate to the p-type NiO layer. The device may also further comprise one or more Au layers proximate to the Ti layer, the Ni layer, or both.

### BRIEF DESCRIPTION OF DRAWINGS

Some embodiments are illustrated in referenced figures of the drawings. It is intended that the embodiments and figures disclosed herein are to be considered illustrative rather than limiting.

FIG. 1A illustrates a schematic cross-section of the NiO/β-Ga₂O₃ heterojunction diode device stack. FIG. 1B provides J-V curves of the device taken at select operating temperatures before and after the completion of 25 high temperature thermal cycles between 25-550° C. Solid lines are measured at the start of cycle 1 and dashed lines are recorded at the end of cycle 25.

FIG. 2 shows TEM Cross-section image of the NiO/β-Ga₂O₃ heterojunction diode after thermal cycling showing the [010] zone for β-Ga₂O₃, NiO, and the [110] zone for NiGa₂O₄. The inset shows a larger view of the NiGa₂O₄ layer, where the atomic model for [110] NiGa₂O₄ is overlaid on the STEM image to show the structural match.

FIG. 3 provides a predicted thermodynamic phase diagram of Ni—Ga—O system as a function of oxygen partial pressure (pO₂) and temperature. The “Experimental Range” box highlights the typical experimental synthesis and operation conditions for devices made from these materials. The parentheses in the figure indicate that depending on the synthesis condition, Ga₂NiO₄ can form as a single phase or coexist with either Ga₂O₃ or NiO/Ni. Inset: shows a Vesta image of inverse spinel NiGa₂O₄ crystal structure (P4₁22). Darker and lighter colors indicate unique sites for Ga and Ni cations. “Up” and “down” refer to applied electron spins.

FIG. 4A illustrates the defect formation energy for lowest-energy native defects of inverse spinel NiGa₂O₄ under the most oxygen-rich condition plotted from VBM (E_{F}=0) to CBM (E_{F}=bandgap). Subscripts indicate different Wyckoff sites. Equilibrium Fermi level of 1.1 eV above VBM is indicated for a synthesis temperature of 873 K. FIG. 4B shows native net acceptor concentrations [Ni_{Ga(oct)}−2 V_{Ni(oct)}] as a function of synthesis temperature and oxygen environment. Experimental synthesis temperature for the NiGa₂O₄ layer is indicated.

FIG. 5A provides semi-logarithmic J-V characteristics of the NiO/NiGa₂O₄/β-Ga₂O₃ HJ diode for different device diameters. Inset shows the schematic of the cross section for the fabricated NiO/NiGa₂O₄/β-Ga₂O₃ HJ diode. FIG. 5B shows reverse J-V characteristics of 300 m diameter NiO/NiGa₂O₄/β-Ga₂O₃ and NiO/β-Ga₂O₃ p-n heterojunctions diodes showing a breakdown voltage of ˜1.18 kV and 703 V, respectively.

FIG. 6 provides a pO2 vs. temperature plot for the Ga—Ni—O system, as described herein.

FIG. 7 illustrates the chemistry and phase coexistence at metal/semiconductor interfaces and the implications related to finding suitable and chemically stable contacts to wide-gap semiconductors.

FIGS. 8A-8C provide the predicted stability of elemental metals in contact with (FIG. 8A) β-Ga₂O₃, (FIG. 8B) rutile GeO₂, and (FIG. 8C) wurtzite GaN at 300 K and any gas partial pressure. Their predicted maximally allowed gas partial pressure (p_{O}² or p_{N}2) for stable metal contacts is also shown. Numbers below the element symbols are metal work functions (see details in the main text). Stable and unstable interfaces are in black and gray, respectively. Elements without boxes are predicted using the Materials Project data.

FIG. 9 shows selected gas partial pressure vs temperature phase diagrams that are relevant for GaN. Compounds within parentheses are competing binary phases for the ternary compounds of interest, and “/” suggests two options based on synthesis conditions.

FIG. 10 provides selected gas partial pressure vs temperature phase diagrams that are relevant for Ga₂O₃ and GeO₂. Compounds within parentheses are competing binary phases for the ternary compounds of interest, and “/” suggests two options based on synthesis conditions.

FIG. 11 illustrates the correlation between formation enthalpy of metal oxides per oxygen atom and metal work function of the constituent metals. The inset illustrates the underlying chemical intuition. Two work function values were reported for Be.

FIG. 12 provides predicted p_{O}2-T phase diagram for the Ga—Ti—O chemical system. Each region is labeled by the compounds that are predicted to form at those conditions. Compounds in parentheses are those predicted to form when the Ga:Ti ratio deviates from 4:1; depending on whether there is an excess of Ti or Ga, different compounds will form (separated by the “/” sign). A large range of p_{O}² values is shown for completeness.

### DETAILED DESCRIPTION

The embodiments described herein should not necessarily be construed as limited to addressing any of the particular problems or deficiencies discussed herein. References in the specification to “one embodiment”, “an embodiment”, “an example embodiment”, “some embodiments”, etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

As used herein the term “substantially” is used to indicate that exact values are not necessarily attainable. By way of example, one of ordinary skill in the art will understand that in some chemical reactions 100% conversion of a reactant is possible, yet unlikely. Most of a reactant may be converted to a product and conversion of the reactant may asymptotically approach 100% conversion. So, although from a practical perspective 100% of the reactant is converted, from a technical perspective, a small and sometimes difficult to define amount remains. For this example of a chemical reactant, that amount may be relatively easily defined by the detection limits of the instrument used to test for it. However, in many cases, this amount may not be easily defined, hence the use of the term “substantially”. In some embodiments of the present invention, the term “substantially” is defined as approaching a specific numeric value or target to within 20%, 15%, 10%, 5%, or within 1% of the value or target. In further embodiments of the present invention, the term “substantially” is defined as approaching a specific numeric value or target to within 1%, 0.9%, 0.8%, 0.7%, 0.6%, 0.5%, 0.4%, 0.3%, 0.2%, or 0.1% of the value or target.

As used herein, the term “about” is used to indicate that exact values are not necessarily attainable. Therefore, the term “about” is used to indicate this uncertainty limit. In some embodiments of the present invention, the term “about” is used to indicate an uncertainty limit of less than or equal to ±20%, ±15%, ±10%, ±5%, or ±1% of a specific numeric value or target. In some embodiments of the present invention, the term “about” is used to indicate an uncertainty limit of less than or equal to ±1%, ±0.9%, ±0.8%, ±0.7%, ±0.6%, ±0.5%, ±0.4%, ±0.3%, ±0.2%, or ±0.1% of a specific numeric value or target.

The provided discussion and examples have been presented for purposes of illustration and description. The foregoing is not intended to limit the aspects, embodiments, or configurations to the form or forms disclosed herein. In the foregoing Detailed Description for example, various features of the aspects, embodiments, or configurations are grouped together in one or more embodiments, configurations, or aspects for the purpose of streamlining the disclosure. The features of the aspects, embodiments, or configurations, may be combined in alternate aspects, embodiments, or configurations other than those discussed above. This method of disclosure is not to be interpreted as reflecting an intention that the aspects, embodiments, or configurations require more features than are expressly recited in each claim. Rather, as the following claims reflect, inventive aspects lie in less than all features of a single foregoing disclosed embodiment, configuration, or aspect. While certain aspects of conventional technology have been discussed to facilitate disclosure of some embodiments of the present invention, the Applicants in no way disclaim these technical aspects, and it is contemplated that the claimed invention may encompass one or more of the conventional technical aspects discussed herein. Thus, the following claims are hereby incorporated into this Detailed Description, with each claim standing on its own as a separate aspect, embodiment, or configuration.

### Example 1—NiGa₂O₄ Interfacial Layers in NiO/Ga₂O₃ Heterojunction Diodes at High Temperature

NiO/Ga₂O₃ heterojunction diodes have attracted attention for high-power applications, but their high temperature performance and reliability remains underexplored. This example describes the time evolution of the static electrical properties in the widely studied p-NiO/n-Ga₂O₃ heterojunction diodes and formation of NiGa₂O₄ interfacial layers when operated at 550° C. Results of our thermal cycling experiment show initial leakage current increase which stabilizes after sustained thermal load, due to reactions at the NiO—Ga₂O₃ interface. High-resolution TEM microstructure analysis of the devices after thermal cycling indicates that the NiO—Ga₂O₃ interface forms ternary compounds at high temperatures, and thermodynamic calculations suggest the formation of the spinel NiGa₂O₄ layer between NiO and Ga₂O₃. First-principles defect calculations find that NiGa₂O₄ shows low p-type intrinsic doping, and hence can also serve to limit electric field crowding at the interface. Vertical NiO/Ga₂O₃ diodes with intentionally grown 5 nm thin spinel-type NiGa₂O₄ interfacial layers show excellent device ON/OFF ratio of >10¹⁰(±3 V), V_{ON} of ˜1.9 V, and breakdown voltage of ˜1.2 kV for an initial unoptimized 300 μm diameter device. These p-n heterojunction diodes are promising for high-voltage, high temperature applications.

The promise of electrical functionality at much higher temperatures compared to existing silicon technologies is one of the major drivers of development in several ultrawide bandgap (UWBG) semiconductor based electronic devices. High temperature operation capability is especially desirable in power devices which find applications in several extreme environmental conditions. Among known ultrawide bandgap semiconductors, β-Ga₂O₃ with a bandgap in the range of 4.5-5.0 eV, and theoretical predicted breakdown electric field of 8 MV/cm, shows remarkable potential for high power, high temperature applications. However, practical development of robust UWBG based power devices capable of reliable operation at high temperatures (>500° C.) requires device interface, contact, and interconnect optimization to eliminate thermal induced premature breakdown, leakages, and possible device failure. Increase in junction temperatures due to Joule self-heating at higher power levels also presents another challenge for >10 A high-power devices, even if operated close to ambient temperature. These considerations are especially important for β-Ga₂O₃-based devices due to the relatively low thermal conductivity in β-Ga₂O₃ compared to other UWBG materials.

Testing of the device characteristics at the desired operating temperature can provide insights on the stability of the electrical properties. β-Ga₂O₃ heterojunction devices utilizing p-type Nickel Oxide (NiO) have been most widely explored due to nickel oxide's favorable band alignment with β-Ga₂O₃ leading to high energy barrier height. Hence, remarkable room temperature (RT) breakdown voltages and correspondingly high Baliga figures of merit have been reported for NiO/β-Ga₂O₃ heterojunctions with various thicknesses of β-Ga₂O₃ drift layer. While NiO—Ga₂O₃ based devices have shown exceptional breakdown characteristics, their application in high temperature environments has not been widely explored. We have shown I-V-T characterization on NiO—Ga₂O₃ diode with potential for operation up to 400° C. with ˜10⁶ current rectification. Others have also shown NiO/Ga₂O₃ high breakdown voltage devices capable of operating at 250° C. and 275° C. respectively.

This example shows the potential of an interfacial NiGa₂O₄ layer to enable NiO/β-Ga₂O₃ vertical heterojunction diodes with robust continuous operation at high temperature. The NiO/β-Ga₂O₃ diodes measured for >200 hours and 25 thermal cycles up to 550° C. show significant degradation of electrical properties, which from transmission electron microscopy can be attributed to chemical reaction and intermixing at the NiO—Ga₂O₃ interface. Thermodynamic calculations suggest a high likelihood for the formation of a ternary compound at this interface—the Ni—Ga—O spinel of the form AB₂O₄. Defect calculations suggest that NiGa₂O₄ is intrinsically weakly p-type with predicted O-rich acceptor carrier density of ˜10¹¹-10¹⁴ cm⁻³ at equilibrium conditions, which can help reduce field crowding thus promoting improved device breakdown. To realize this promise, we intentionally grow spinel-type NiGa₂O₄ as a 5 nm thin interlayer at NiO/Ga₂O₃ interface. Fabricated NiO/NiGa₂O₄/Ga₂O₃ vertical heterojunction diodes on a 5-μm thick HVPE-Ga₂O₃ sample show a rectification ratio of >10¹⁰ (±3 V). Breakdown voltage (V_{br}) of 1.2 kV for a large area (300 μm) device without optimized electric field management techniques is obtained, compared to a V_{br} of 700 for a similar NiO/Ga₂O₃ device without the intentionally grown thin NiGa₂O₄ layer. This NiO/NiGa₂O₄/Ga₂O₃ structure is promising for optimizing the device breakdown by spreading the peak electric field, and for passivating interfacial reactions to achieve high voltage devices that can be operated continuously at high temperatures.

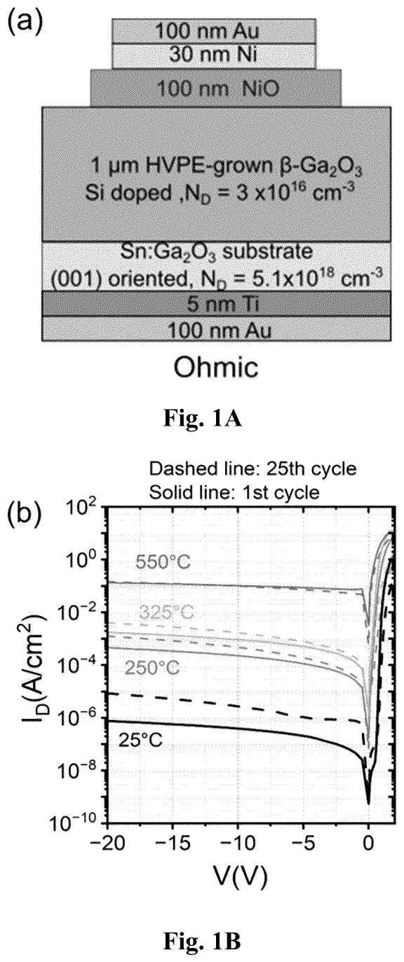

The vertical NiOₓ/p-Ga₂O₃ heterojunction diode sample used for thermal cycling experiment was fabricated on a 1-μm lightly Si-doped (3×10¹⁶ cm⁻³) n-type β-Ga₂O₃ drift layer grown on a conductive bulk (001) β-Ga₂O₃ substrate (NCT). The schematic of the device cross-section is shown in FIG. 1A. Ohmic contact of Ti/Au (5 nm/100 nm)²² was deposited on the backside of the substrate via e-beam evaporation, followed by a rapid thermal annealing (RTA) in N₂ ambient at 550° C. for 1 min. Next, the NiO were grown by pulsed laser deposition as described previously¹⁸. For the front-side ohmic contact on NiO, contact aligner lithography was used to make circular contact patterns of 50-300 μm diameter followed by e-beam evaporation of Ni/Au (30 nm/100 nm). To test the device stability under sustained thermal stress, the fabricated NiO/β-Ga₂O₃ vertical heterojunction diodes were subjected to multiple temperature cycle between 25-550° C. (up to 25 cycles over >200 hours) with in-operando I-V characterization.

Device J-V characteristics measured during the thermal cycling experiment conducted on a 300 μm diameter NiO/β-Ga₂O₃ heterojunction diode are shown in FIG. 1B before and after 25 thermal cycles conducted between 25° C.-550° C. We observe ˜1 order of magnitude increase in the leakage current density at −20 V bias for measurements at 25° C. after 25 thermal cycles, but the change is less pronounced for measurements at 550° C. Similar degradation in the forward current is observed for the different temperatures after the 25 cycles. These differences (increase in leakage current and decrease in forward current) point to the presence of a thermal induced degradation process, likely an interfacial reaction that saturates at 550° C. An indication of this self-limiting temperature-induced interfacial reaction can be seen in the analysis of the leakage current density at −20V for the different temperatures across the 25 cycles. We observe that the increase in the leakage current with cycling present in FIG. 1B was only up to the 5^{th} cycle. After the 5^{th} cycle the changes in the leakage current became negligible, suggesting the saturation of the interfacial reaction. We focus on the NiO—Ga₂O₃ interfacial reaction, because our previous work found that Ti/Au(5 nm/100 nm) ohmic contacts to β-Ga₂O₃ show stable electrical properties for operation at 600° C.

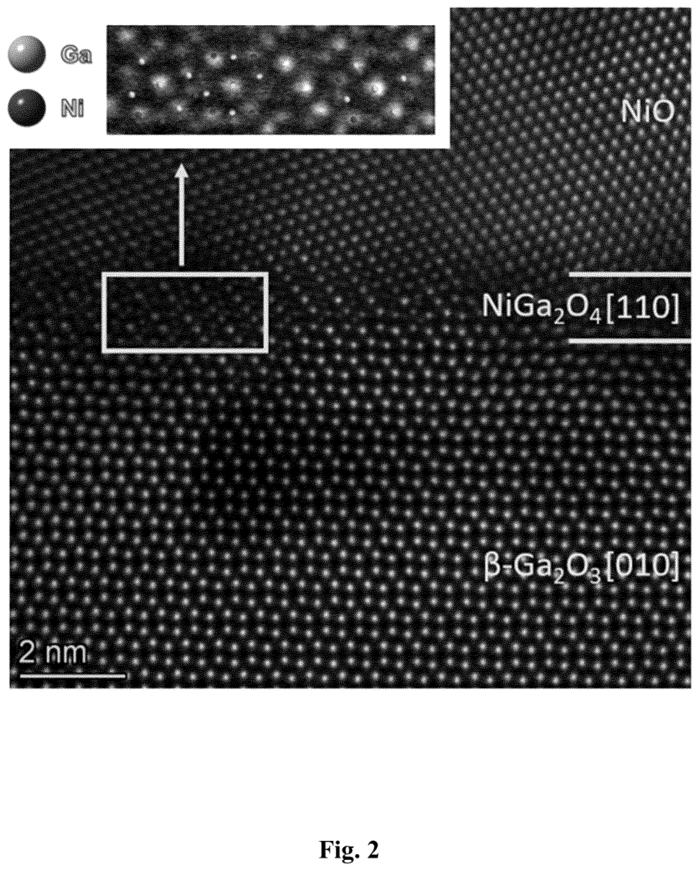

To explore the NiO/β-Ga₂O₃ interfacial reaction, cross-section scanning transmission electron microscopy (STEM) was performed on the NiO/β-Ga₂O₃ device after the thermal cycling experiment. The TEM foil was prepared using the Helios NanoLab 600 DualBeam focused ion beam (FIB), and ion milled at 900V with a Fischione Nanomill to clean the surface of the foil. The STEM investigation was performed on an aberration-corrected Themis-Z from Thermo Fisher Scientific. FIG. 2 shows the cross-section of the NiO and β-Ga₂O₃ interface. Between the NiO and β-Ga₂O₃ interface is a layer approximately 2 nm in thickness where cubic spinel NiGa₂O₄ begins to form. The atomic models of NiGa₂O₄ along the [110] direction match the atomic structure of the measured NiGa₂O₄ region. There appears to be some level of disorder within the NiGa₂O₄ layer as the NiGa₂O₄ structure is not uniform, showing different possible rotations or orientations of the NiGa₂O₄ structure within the 2 nm region of NiGa₂O₄. We also note that these layers might be Ni-substituted γ-phase Ga₂O₃ defective spinel.

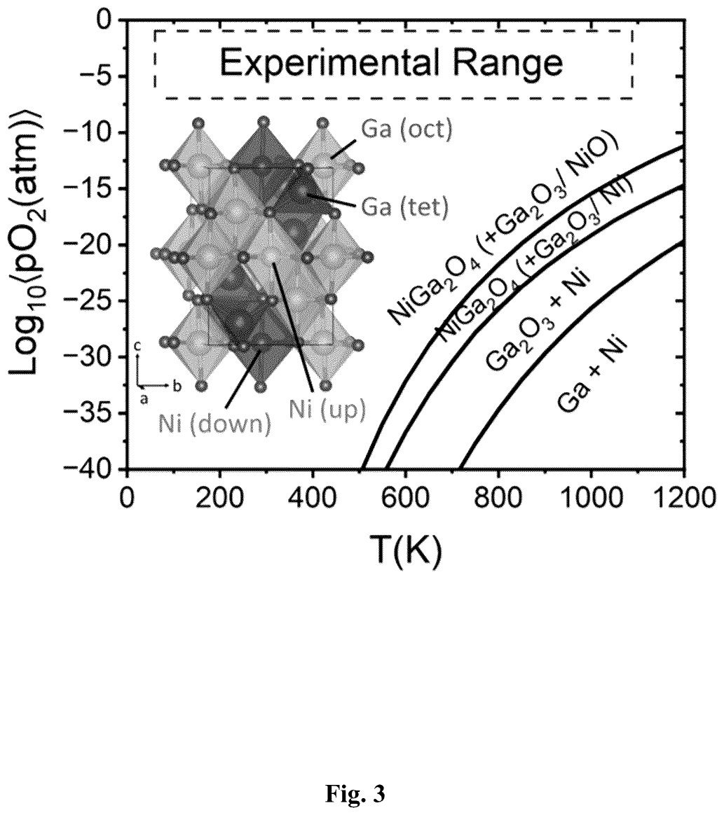

To explain the possible outcomes of interfacial reactions in the NiO—Ga₂O₃ heterostructure during operation at high temperature, as observed in electrical data from the thelnal cycling experiment in FIGS. 1A-1B and the microstructure analysis using TEM in FIG. 2, we study the thermodynamic phase diagram of the Ni—Ga—O system. We follow the approach recently developed and calculate the oxygen partial pressure vs. temperature (pO₂-T) phase diagrams using a density functional theory dataset (NREL MatDB) and correction scheme that ensures chemical accuracy (˜50 meV/atom) and captures temperature dependency. FIG. 3 shows the calculated phase diagram of Ga—Ni—O system for a wide range of temperatures and oxygen partial pressures (pO₂). For the typical experimental synthesis and high temperature operating conditions, the NiO/Ga₂O₃ interface is chemically unstable based on this calculation. Instead, these conditions in the experimental range favor the formation of NiGa₂O₄ with spinel structure shown in the inset of FIG. 3, supporting the observed spinel NiGa₂O₄(or Ni-substituted y-phase Ga₂O₃) found from TEM analysis of the NiO—Ga₂O₃ interface after thermal cycling.

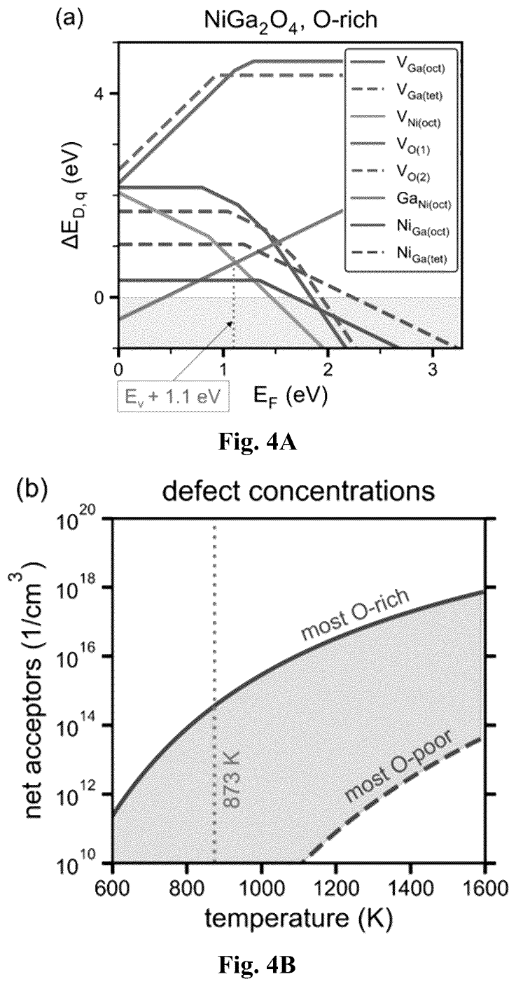

To better understand the potential impact of NiGa₂O₄ on the device performance as an interlayer in NiO—Ga₂O₃ heterojunction, we investigate the native charged point defect energetics of NiGa₂O₄ using density functional theory (DFT) calculations. We model the ordered inverse spinel (P4₁22) NiGa₂O₄ crystal structure with anti-ferromagnetic spin since this is the lowest energy configuration according to our calculations. Its calculated GW band gap is ˜3.3 eV. The formation energies of the lowest energy native defects are shown in FIG. 4A for the most oxygen-rich synthesis condition. The most relevant defects for p-type doping are those with low formation energy near the valence band edge (E_{F}=0 eV). Ga_{Ni} substitutional is a shallow compensating donor, while the Ni_{Ga} substitutionals on both the tetrahedral and octahedral sites are deep acceptors. The appearance of low energy octahedral cation anti-sites suggests NiGa₂O₄ will likely be a disordered inverse spinel (Fd3m space group) which is consistent with the findings of previous computational studies. Due to its deep (0/−1) charge transition level, Ni_{Ga} cannot act as an intrinsic dopant. However, Ni vacancies (V_{Ni}) can provide acceptors. Altogether, this sets an equilibrium Fermi level about 1.1 eV above the valence band edge, indicating that this material is weakly intrinsic p-type. In addition, there may be room to increase the number of holes beyond those provided from V_{Ni} with an extrinsic acceptor dopant. While thin films of NiGa₂O₄ have seldom been reported, microstructured NiGa₂O₄ samples have been demonstrated as p-type materials useful for gas sensing, water splitting and energy storage applications, which is consistent with results of our theoretical calculations.

We also use thermodynamic modeling to estimate the net acceptor concentration for a given temperature and chemical potentials, assuming a standard effective density of states for intrinsic carrier concentrations and an Arrhenius relationship for charged defects. FIG. 4B shows the achievable net acceptor concentration for intrinsic NiGa₂O₄ within the bounds of its thermodynamic stability from decomposition. Considering thermodynamic equilibrium, we would expect net acceptor concentrations to range from below 10¹⁰ to 1018 cm⁻³ depending on the synthesis conditions. For the conditions used in our experiments (T=873K; pO2=10⁻³ Torr), we predict an equilibrium net acceptor concentration ˜10¹¹-10¹⁴ cm⁻³ in our NiGa₂O₄ layer.

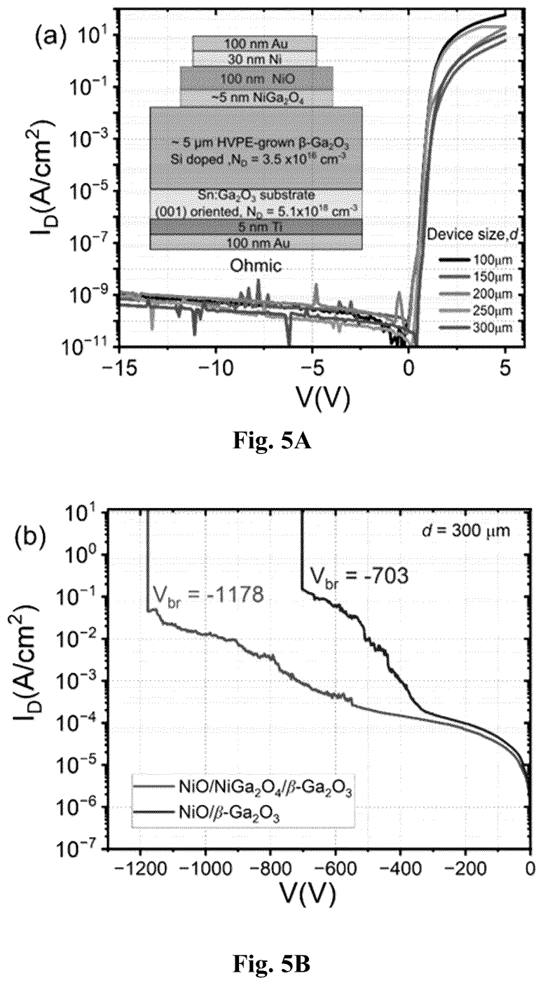

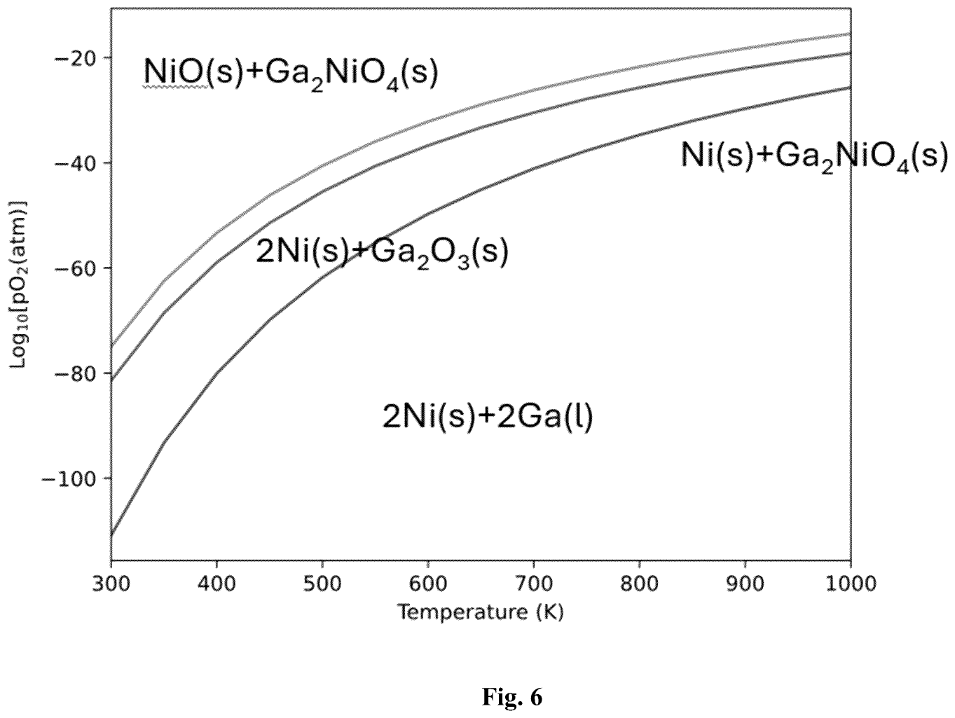

Next, we demonstrate vertical heterojunction NiO/NiGa₂O₄/β-Ga₂O₃/n⁺Ga₂O₃ diodes (FIG. 5A employing thin NiGa₂O₄ thin films intended as a passivation layer at the NiO—Ga₂O₃ interface for high temperature applications. For these devices, NiGa₂O₄ and NiO layers were grown by pulsed laser deposition on ˜5 m lightly doped n-type Ga₂O₃ drift layer without breaking vacuum to facilitate a high quality NiO/NiGa₂O₄ hetero-interface. This was done to achieve a homogeneous NiGa₂O₄ layer of the same orientation and thickness throughout the device, rather than a randomly nucleated NiGa₂O₄ islands observed in TEM (FIG. 2). Then devices were fabricated and characterized as described above. The room temperature semi-logarithmic current-voltage (J-V) curves for the fabricated heterojunction p-n diode are shown in FIG. 5A for different values of the device diameter. The diode turn-on voltage (V_{ON}) defined at the forward current density of ˜10 A·cm⁻² is 1.9V for the NiO/NiGa₂O₄/Ga₂O₃ diode and a diode rectification (I_{ON}/I_{OFF}) ratio ˜10¹⁰(±3V) is obtained for this diode. In contrast, NiO/Ga₂O₃ devices fabricated without the thin NiGa₂O₄ layer show a lower V_{ON} of 1.7 V and similar I_{ON}/I_{OFF} ratio. The minimum differential specific on-resistance, R_{on,sp} obtained for the NiO/NiGa₂O₄/Ga₂O₃ devices is 0.04 Ω-cm², which is higher compared to 0.03 Ω-cm² for the NiO/Ga₂O₃ device without the NiGa₂O₄ layer.

Breakdown voltages (V_{br}) at which the devices show catastrophic failure are shown in the reverse J-V characteristics in FIG. 5B for NiO/5 μm n⁻β-Ga₂O₃/n⁺Ga₂O₃ heterojunction devices with and without a thin NiGa₂O₄ layer. The breakdown voltage (V_{br}) at room temperature was measured with the samples fully immersed in FC-40 Fluorinert dielectric liquid using a Keysight B1505A Power device Analyzer with a reverse current limit of 1 mA. Measurement results show that the NiO/NiGa₂O₄/Ga₂O₃ devices have lower leakage current, and a higher breakdown voltage, V_{br}=1.2 kV compared to 700 V for the NiO/Ga₂O₃ devices. This is attributed to the thin NiGa₂O₄ serving to provide improved edge termination resulting in suppressed electric field crowding in the device. Hence, NiGa₂O₄ is promising for a combined role of passivation layer for high temperature operation and voltage blocking layer for electric field management in NiO/NiGa₂O₄/Ga₂O₃ heterojunction p-n devices.

In summary, we showed NiGa₂O₄ as a p-type interfacial layer to improve the stability of the electrical properties in NiO/β-Ga₂O₃ heterojunction diode, as motivated by observed degradation in the electrical properties due to temperature induced interfacial instability. We showed the controlled thin film growth of the NiO/β-Ga₂O₃ reaction product (NiGa₂O₄) as an interfacial layer integrated in NiO/NiGa₂O₄/β-Ga₂O₃ heterojunction vertical power diodes contribute to the enhanced device reverse blocking capability. Non-field plated NiO/NiGa₂O₄/β-Ga₂O₃ heterojunction with I_{ON}/I_{OFF} ratio and V_{ON} of 10¹⁰ (±3 V) and 1.9V, respectively, supports a high breakdown voltage of 1.2 kV for 300 m device compared to 700 V for the NiO/Ga₂O₃ devices, due to NiGa₂O₄ layer providing improved edge termination and reduced electric field crowding. Optimization of the conductivity and the carrier density of the NiGa₂O₄ layer through defect engineering and extrinsic doping should further improve device performance. The integration of thin NiGa₂O₄ layers between NiO and β-Ga₂O₃ is promising for realizing high performance β-Ga₂O₃ based vertical p-n devices with stable electrical performance at extreme environments such as at high temperatures.

### Example 2—Computational Insights into Phase Equilibria Between Wide-Gap

### Semiconductors and Contact Materials

Novel wide-band-gap semiconductors are needed for next-generation power electronics, but there is a gap between a promising material and a functional device. Finding stable (metal) contacts is one of the major challenges that is currently dealt with mainly via trial and error. Herein, we computationally investigate the thermochemistry and phase coexistence at the junction between three wide-gap semiconductors, β-Ga₂O₃, GeO₂, and GaN, and possible contact materials. The pool of possible contacts includes 47 elemental metals and a set of 4 common, n-type transparent conducting oxides (ZnO, TiO₂, SnO₂, and In₂O₃). We use first-principles thermodynamics to model the Gibbs free energies of chemical reactions as a function of gas pressure (p_{O}²/p_{N}2) and equilibrium temperature. We deduce whether a semiconductor/contact interface will be stable at relevant conditions or a chemical reaction between them is to be expected, possibly influencing the long-term reliability and performance of devices. We generally find that most elemental metals tend to oxidize or nitridize and form various interface oxide/nitride layers. Exceptions include select late- and post-transition metals and, in the case of GaN, also the alkali metals, which are predicted to exhibit stable coexistence, although in many cases at relatively low gas partial pressures. Similar is true for the transparent conducting oxides, for which, in most cases, we predict a preference toward forming ternary oxides when in contact with β-Ga₂O₃ and GeO₂. The only exception is SnO₂, which we find to form stable contacts with both oxides. Finally, we show how the same approach can be used to predict gas partial pressure vs temperature phase diagrams to help direct synthesis of ternary compounds. These results provide valuable guidance in selecting contact materials to wide-gap semiconductors and suitable growth conditions.

### INTRODUCTION

It is challenging to find suitable contact materials for wide-band-gap (WBG) semiconductors, in particular for power electronic devices. Namely, while novel wide-gap (WG) and ultrawide-gap (UWG) semiconductors are critically needed as the basis for the next-generation power conversion devices capable of meeting the demands of the expected broad future electrification and adoption of renewable energy technologies, having the promising active material alone is not sufficient. Each new WBG/UWBG semiconductor must be accompanied by suitable contact materials for the devices to operate as desired.

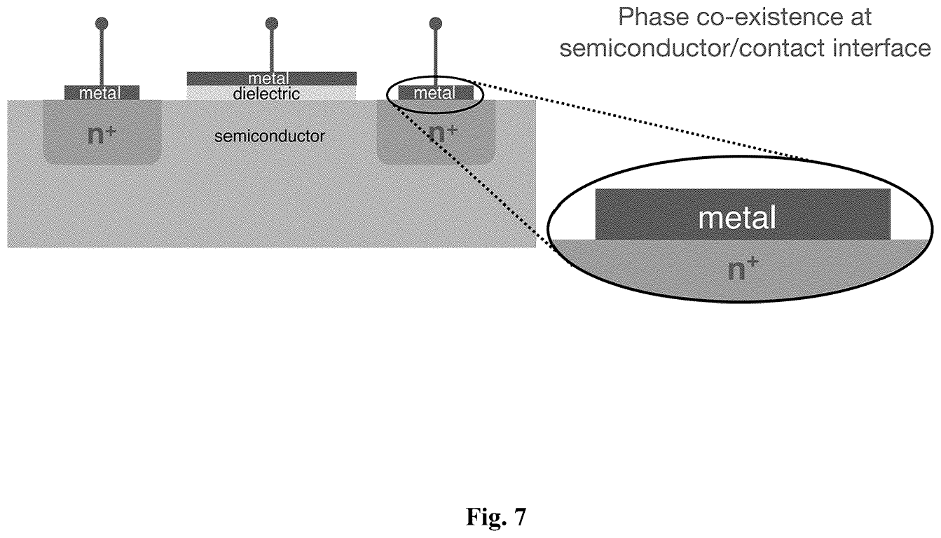

For any given WBG/UWBG semiconductor, suitable contacts need to fulfill a number of criteria. The list usually starts with electronic properties including electric conductivity of a certain magnitude, favorable Schottky barrier, and/or or band alignment with the active material, lack of problematic interface states, etc. However, many of these relevant quantities depend on the details of interface chemistry and the formation of secondary phases (or not) between active materials and contacts (FIG. 7). Regardless, whether the interface chemistry is helpful, as may happen in some instances, or harmful for the device performance, the knowledge of what exact phases are present at the interface is vital for all aspects of device engineering. This is particularly true for high-power and/or high-temperature electronic devices as the Joule heating due to large current densities in combination with frequent switching will likely lead to the equilibration of the system over long periods of time.

Interface chemistry or stability (whether two materials in contact with one another can coexist without spontaneous chemical reactions) can be evaluated from (a) the knowledge of chemical reactions that could potentially happen and (b) the Gibbs free energies of formation of all reactants and products of those chemical reactions. In the case of oxidation-reduction reactions this could be done using the Ellingham diagrams, for example. However, experimental thermochemical data, including the Gibbs free energies of formation (ΔG_{f}) as well as the enthalpies of formation (ΔH_{f}), for ternary and other multinary compounds are not as available as for the binary ones. Hence, the chemistry that is likely to occur at the interface between WBG/UWBG materials, which are often binary compounds, and their contacts, often elemental metals or compounds themselves, cannot be generally predicted solely from the experimental data.

In order to study the possible chemical reactions at the junction between WBG/UWBG semiconductors and their contacts in this paper, we utilize computational resources and methods that allow interface chemistry and phase coexistence (i.e., the phase equilibria) to be evaluated more broadly and for larger range of compounds. First, we use the calculated enthalpies of formation stored in various computational materials databases, in combination with the modeled phonon contributions to the Gibbs free energies following the work by Bartel et al. In this way, predictions of the temperature-dependent, compound ΔG_{f} values for virtually any stoichiometric and ordered compound can be made and used to compute the reaction free energies. Similar methodologies to predict grand potential phase diagrams from first principles have been used for multiple applications and adding phonon contributions to the Gibbs free energies improves the prediction accuracy beyond room temperature. Besides, the scope of this paper mainly focuses on the applications. Second, the data stored in computational materials databases cover not only experimentally realized ternary and other multinary compounds but also the hypothetical ones that could potentially form, providing the unprecedented list of possible solid phases and hence possible reaction products.

With the use of these databases, primarily the NREL computational materials database (NRELMatDB) and the Materials Project, we assess the interface chemistry and phase coexistence of 47 elemental metals and 4 commonly used transparent conducting oxides when in contact with β-Ga₂O₃, rutile GeO₂, and GaN. This set of materials covers novel WBG semiconductors (β-Ga₂O₃), recently proposed ones (rutile GeO) as well as a well-established wide-gap semiconductor (GaN). In short, we find that most elemental metals tend to form various interface oxide/nitride layers. Exceptions include select late- and post-transition-metals and, in the case of GaN, also the alkali metals, which are predicted to exhibit stable coexistence. Contrary to Ga₂O₃ and GeO₂ for which stable coexistence with most of those elemental metals occurs at relatively low gas partial pressures, junctions between GaN and metals are predicted to survive to high N₂ pressures owing to the strong triple bond in the N₂ molecule (oxygen is not considered in the analysis). The same is true for the TCOs, for which in most cases we predict a preference toward forming ternary compounds with Ga₂O₃ and GeO₂. The only exception is SnO₂, which can coexist with both Ga₂O₃ and GeO₂ and form a stable contact. In what follows we describe the methods and results in greater detail and discuss the guidelines distilled from theory in choosing contact materials and appropriate growth conditions.

### Results and Discussion

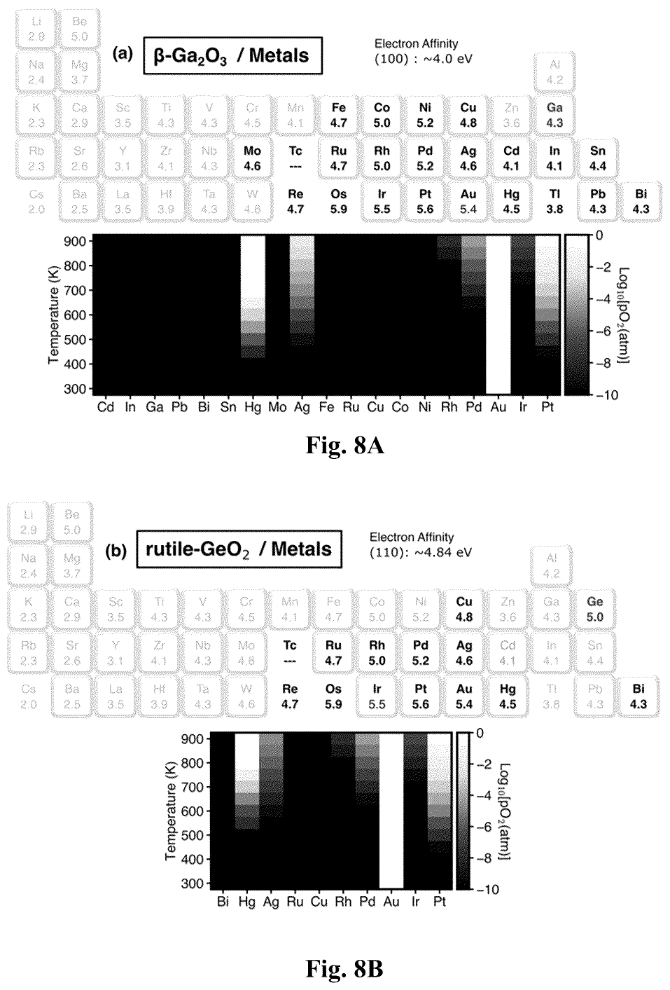

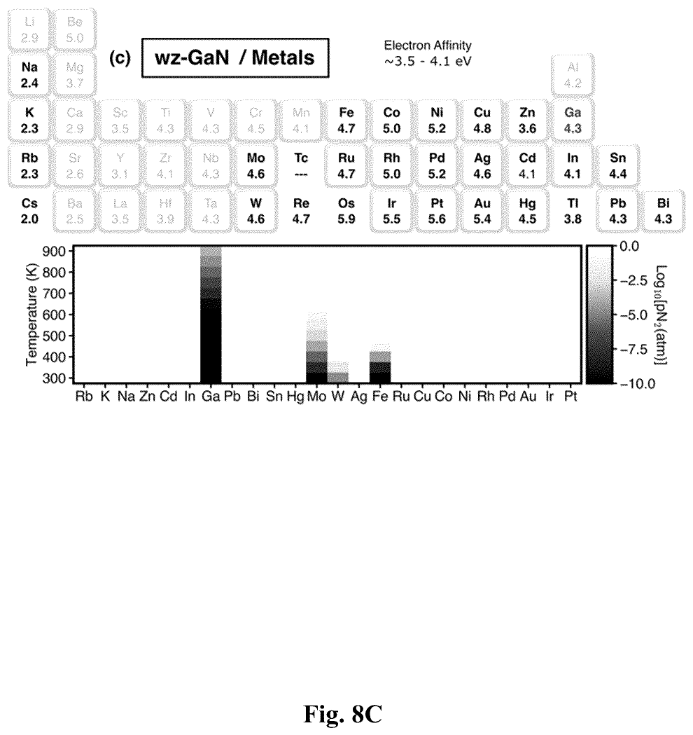

Stability of Elemental Metals in Contact with Wide-Gap Semiconductors. Using the first-principles thermodynamic modeling described in detail in the Materials and Methods section of this example, we estimate the interface stability between a range of elemental metals and three wide-gap semiconductors (Ga₂O₃, GeO₂, and GaN). Generally, our approach is robust in predicting Gibbs formation energy (<50 meV/atom), and the predicted gas partial pressure is therefore expected to be accurate within 1-2 orders of magnitude due to exponential dependency of partial pressure on the formation energy (see the Materials and Methods section for details). The results are summarized in FIGS. 8A-8C. Sections of the periodic table show all the elemental metals we investigated, and the three panels correspond to the three wide-gap systems. Stability information is presented in the following way. Chemical symbols in black correspond to the metals that are predicted to stably coexist with each wide-gap system at 300 K and some gas partial pressure. The effect of a temperature increase on stability assessment is that maximal partial pressure at which a given metal starts to oxidize or nitridize will shift to higher values. This effect can be observed in the bottom subpanels of each panel, where the maximal gas pressures for the stable coexistence are shown as a function of temperature for the subset of metals that are declared stable at 300 K. The black color denotes maximal gas pressure values equal to or below 10⁻¹⁰ atm. In contrast, metals that are predicted to form compounds (binary, ternary, etc.) at 300 K and any gas pressure when in contact with our wide-gap systems are shown in gray and declared unstable. This classification is robust with respect to changing conditions, as those metals that are predicted unstable at all gas pressures at 300 K are not going to become stable at temperatures above 300 K and any physically reasonable gas pressures. In other words, the maximal partial pressure for the interfaces that become stable at higher temperature is expected to be far below 10⁻¹⁰ atm.

It becomes clear that for Ga₂O₃ and GeO₂ every metal would oxidize above a certain gas pressure, and the pressures before this happens are below 10⁻¹⁰ atm for most elemental metals.

Only for a subset of metals, the noble ones mainly (plus Hg), do we find oxidation to occur atp 10⁻¹⁰ atm. The situation is markedly different in the case of GaN (oxygen is not considered in the analysis). First, a larger range of elemental metals are predicted to stably coexist with GaN at 300 K, including nearly the entire right half of the periodic table and alkali metals (Na, K, Rb, and Cs). This result is a consequence of the much lower number of binary and ternary nitride compounds in comparison to the oxides, which results from the much lower and even positive enthalpies of formation. The work of Sun et al. reveals that no new ternary nitrides composed of Ga and other elemental metals are thermochemically stable. The same observation applies to the corresponding binary nitrides most of which have positive enthalpies of formation. Second, most of the metals that are predicted to stably coexist with GaN can survive to relatively high N₂ pressures. Only Mo, W, and Fe are predicted to form nitride compounds below ˜500 K.

Metal Contact Selection Based on Stability and Metal Work Function. Now we turn to discussing the type of contacts (Schottky or Ohmic) metals that are predicted to stably coexist at some gas pressures and temperatures would form with the three WBG semiconductors. To find an elemental metal that would stably coexist and form an Ohmic contact with the n-type β-Ga₂O₃, a metal with a work function (WF) around 4.0 eV is needed. This is based on the qualitative Schottky-Mott rule and the value for the electron affinity of β-Ga₂O₃ that is ≈4.0 eV for the (100) surface. Given the largely qualitative nature of the Schottky-Mott rule, we set the target metal WF to be lower than 4.5 eV, which singles out Ga, Cd, In, Tl, Pb, and Bi as the potential stable metal Ohmic contacts for β-Ga₂O₃. However, there are two limitations regarding these metals. First, they all have low melting points (<350° C.), and such property prevents them from high-temperature applications (>400° C.). Furthermore, they generally require low oxygen partial pressures (<10⁻¹⁰ atm) to maintain a stable metal/β-Ga₂O₃ interface. Hence, our stability analysis suggests that stable Ohmic contacts under typical operating and/or synthesis conditions are unlikely to be found among elemental metals.

Qualitatively similar results are obtained in the case of rutile GeO₂, which was proposed recently to be a promising wide-gap semiconductor material. Metals that are predicted to form a stable interface with rutile GeO₂ generally have high work functions. Among them, only a few noble metals (Au, Hg, Pt, Ag, Pd, Ir, and Rh) are predicted to form stable GeO₂/metal interfaces under practical operation conditions (p_{O}²>10⁻¹⁰ atm). Considering the predicted electron affinity of ˜4.84 eV calculated by HSE06+G₀W₀, Ag and Ru, with work functions of 4.6 and 5.0 eV, respectively, are predicted to be stable metal Ohmic contacts for the n-type doped rutile GeO₂, albeit at very low p_{O}². Rutile GeO₂ is also predicted to exhibit ambipolar doping behavior; i.e., rutile GeO₂ can be not only n-type but also p-type conductor. In the case of p-type doping and with a predicted ionization potential of the rutile GeO₂ of 9.5 eV for the (110) surface, there are practically no metals that can form metal Ohmic contact according to the Schottky-Mott rule.

Lastly, we discuss wurtzite GaN, which has different thermochemical properties compared to two WBG oxides. FIGS. 8A-8C shows that alkali metals, except for Li, can form stable interfaces with GaN. This observation is unintuitive at first glance, given that alkali metals are known to be reactive with oxygen molecules. Further investigations into the phase equilibria of Ga—N-alkali systems show that only Li can form a stable ternary compound (Li₃GaN₂) that prevents coexistence between Li and GaN. Heavier alkali metals (M═K, Na, Rb, and Cs) can form MN₃ compounds, but the formation energies are not low enough to prevent coexistence with GaN.

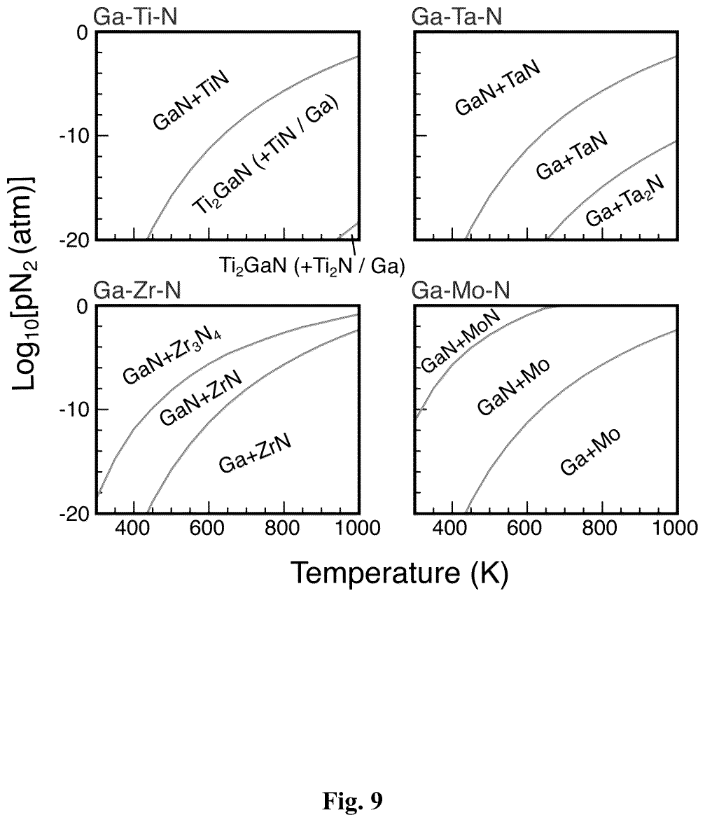

Considering the extended use of Ti as metal contact for GaN in the literature, we performed a detailed analysis on the predicted results of GaN/Ti interfaces. FIG. 9 shows that wz-GaN/Ti interfaces are not stable, and further investigations into phase equilibria show that Ti will form TiN or Ti₂GaN, both of which have low enough formation energy to prevent coexistence between Ti and GaN. However, we note that these are conductive metal nitrides, and the conductivity at the interface is likely still high irrespective of the formation of various Ti—N phases. The predicted phase diagram is consistent with a diffusion couple experiment of GaN/Ti annealed at 850° C. for 160 h under Ar air. The samples have a diffusion path of GaN/TiN/Ti₂GaN/Ti₃Ga/Ti, which supports our prediction that TiN coexists with GaN and Ti₂GaN can form with lower p_{N}2 or equivalently lower N chemical potential, i.e., closer to the Ti metal. Ta and Mo are another two common metal contacts for GaN, and FIG. 9 shows that the wz-GaN/Ta interface is not stable, while the wz-GaN/Mo is predicted to be stable in the middle part of the corresponding phase diagram in FIG. 9. The predicted phase diagram is consistent with experimental observations that GaN/TaN interfaces are stable up to annealing temperature of 1000° C. while Mo/GaN interfaces degrade in ambient nitrogen due to formation of nitride phases. Similar to TiN, TaN and MoN are also electrically conductive. Lastly, we look at the stability of the ZrN/GaN interface. ZrN is a conductive nitride commonly used as metal contact and diffusion barrier for GaN. We notice that the ZrN/GaN interface can be stable at certain synthesis conditions, but at lower temperature and/or higher nitrogen partial pressures Zr₃N₄ will form, which is instead a semiconductor. This suggests that control of nitrogen partial pressure is needed to maintain long-term stability of ZrN/GaN interfaces. While GaN/ZrN interfaces are reported to be stable up to annealing temperature of 1000° C., there is no report on Zr₃N₄, which requires a fairly nitrogen-rich condition.

Transparent Conducting Oxides as Ohmic Contacts to Ga₂O₃ and GeO₂. Given the apparent absence of elemental metals that would stably coexist with β-Ga₂O₃ and form Ohmic contacts, we examine the possibility of using transparent conducting oxides in their place. The considered TCOs, including TiO₂, ZnO, In₂O₃, and SnO₂, are generally dopable to high electron concentrations, and since they are oxides themselves, it would be expected for them to form stable coexistence with other WBG oxides. This expectation is under examination here. If stable, TCOs may provide a solution to the Ohmic contact problem because when used as a buffer layer between the WBG semiconductor and an elemental metal, the highly doped TCO may help create an effective Ohmic contact due to the high charge carrier concentration and/or suitable band alignment.

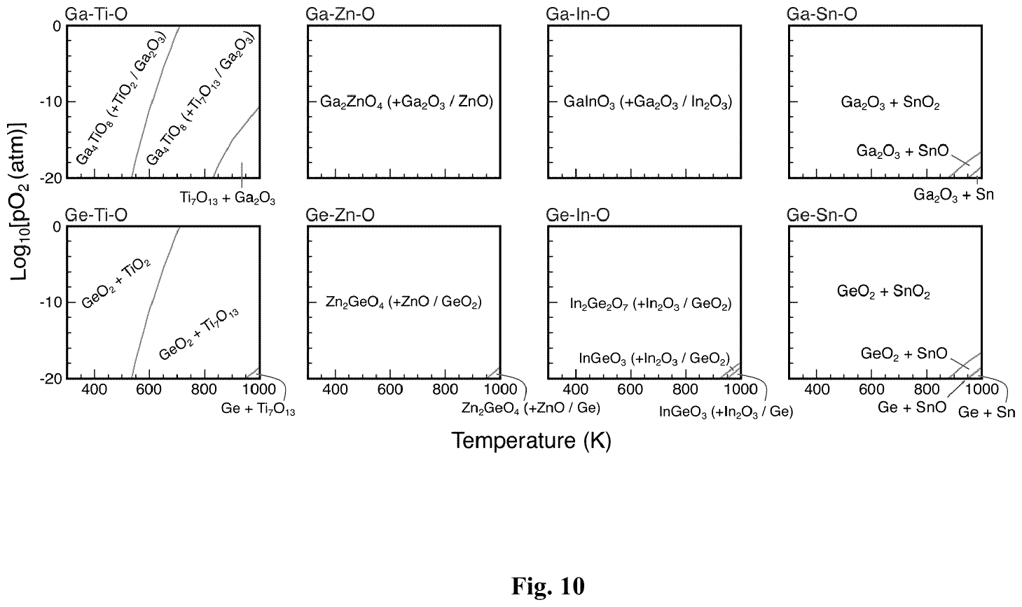

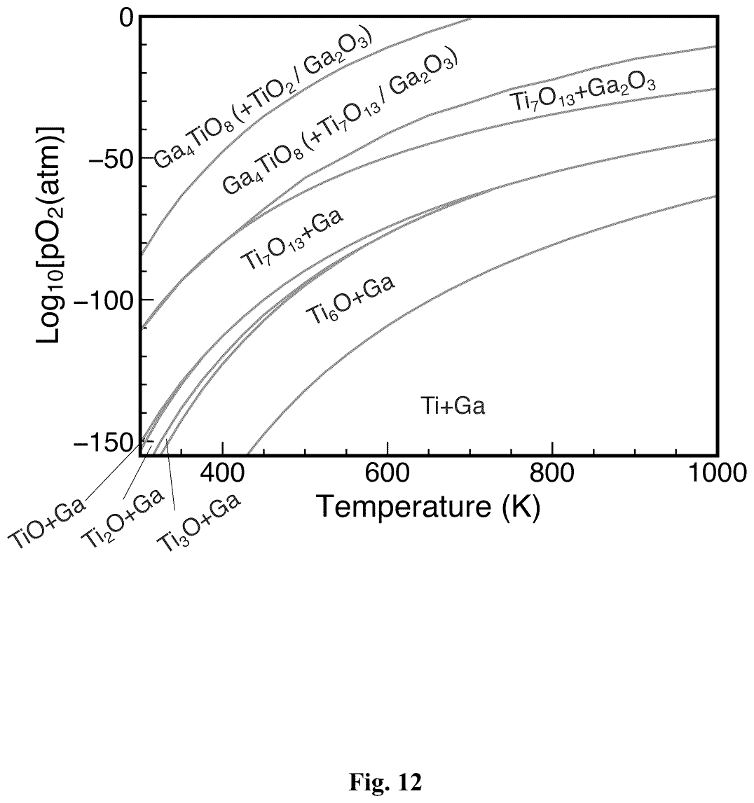

Our results illustrated in FIG. 10 show that neither ZnO nor In₂O₃ can coexist with β-Ga₂O₃ but would rather form ternary oxides. Formation of the Ga₂ZnO₄ spinel and GaInO₃ compound, respectively, is predicted to occur when in contact with β-Ga₂O₃. However, it is important to note that Ga₂ZnO₄ itself is a n-type material and that formation of Ga₂ZnO₄ might not be necessarily bad for the device performance, although the interface characteristics will depend on the chemistry. The case of the Ga—Ti—O chemical system that was already discussed in the context of FIG. 12 deserves a little more attention. Namely, while the conclusion that β-Ga₂O₃ does not stably coexist with elemental Ti is robust, the conclusion suggested by FIG. 10 that there is no coexistence with TiO₂ either may be questionable. This is because the reaction free energy between TiO₂ and β-Ga₂O₃ to form Ga₄TiO₈ is predicted to be only ˜−b 11 meV/atom at 300 K, which is within the error bar of our method. Similarly, the formation of GaInO₃ is also within ˜10 meV/atom. Consistent results can be obtained from the Materials Project and the OQMD databases. Hence, the Ga₄TiO₈ and GaInO₃ are only marginally stable according to our calculations, and as a result, the stable coexistence with β-Ga₂O₃ may be a function of specific conditions at the interface that go beyond bulk thermodynamics (e.g., strain, local fluctuations of thermodynamic parameters, etc.). Experimentally, limited thermal stability studies exist only for ITO/Ga₂O₃ interfaces, which degrade at elevated temperature (>300° C.), and the observations are consistent with our prediction.

In conclusion, the only TCO out of the 4 that we find to robustly coexist with β-Ga₂O₃ without potentially forming ternary oxides is SnO₂. For the rutile GeO₂ we find a stable coexistence with both TiO₂ and SnO₂ while the formation of ternaries Zn₂GeO₄ and In₂Ge₂O₇ is predicted to occur for ZnO and In₂O₃. The formation of the ternary compounds is in this case outside of the error bars of our methodology, and these predictions are considered robust. The differences in electron affinities between SnO₂ (˜5.3 eV²⁷), Ga₂O₃(˜4.0 eV¹⁹), and GeO₂ (˜4.8 eV) are also relatively large, which suggests that engineering of the Ohmic type contact by adjusting electron concentrations (doping) and the corresponding Fermi levels in both Ga₂O₃/GeO₂ and SnO₂ is likely required. This will, of course, depend on the details of the atomic structures at the interface.

Phase Diagrams for Synthesis of Ternary Com-pounds. The surge in computational materials discovery has led to a growing candidate list of ternary and multinary compounds, which are generally more challenging to grow due to a larger parameter space than binary compounds. The gas partial pressure versus temperature phase diagrams generated computationally are also useful tools to reduce the synthesis parameter space. Taking the ternary compounds in FIGS. 9-10 as examples, we can deduce the guidelines to grow single-phase Ga₂ZnO₄, GaInO₃, Zn₂GeO₄, Ti₂GaN, Ga₄TiO₈, and In₂Ge₂O₇ using the phase diagrams. For the former three ternary compounds, the phase diagrams suggest that at a typical growing pressure and temperature, e.g., the ranges shown in FIGS. 9-10, ternary compounds are predicted to be stable, and whether we can grow single-phase crystals depends on fine-tuning the cation ratio to avoid secondary phases. We note that vapor pressure of constituent metals or metal (sub)oxides will affect the tuning but are not considered in this work. For the latter three compounds, synthesis requires further control of gas pressure and temperature in addition to balancing cation ratios. Specifically, a lower temperature is needed to grow Ga₄TiO₈ because it is no longer a stable compound at higher temperature since it decomposes into Ti₇O₁₃, and Ga₂O₃ (see their coexistence curve in FIG. 10). In contrast for Ti₂GaN, a higher growing temperature is needed because the coexistence of GaN and TiN is energetically more favorable than Ti₂GaN at lower temperature (see FIG. 9). Lastly, because the oxygen-deficient phase (InGeO₃) for In₂Ge₂O₇ is more energetically stable at high temperature and low oxygen partial pressure, such growing conditions should be avoided. Overall, the generated phase diagrams provide qualitative but practical guidance to grow a target single-phase ternary compound.

Qualitative Correlation between the Metal Oxide Formation Enthalpies and the Metal Work Functions. Based on thermochemical stability predictions for metal/oxide interfaces studied in this work, we noticed the following trend. Metals with smaller work functions, i.e., Fermi level closer to vacuum, are generally less stable when in contact with β-Ga₂O₃ or GeO₂. In other words, their oxides are more likely to form than oxides of the metals with higher work functions. Furthermore, using β-Ga₂O₃/metal coexistence as an example, we found that metals which are more likely to form oxides when in contact with β-Ga₂O₃ generally have their work functions lower than the work function of elemental Ga (˜4.3 eV). These two observations indicate that metals with lower work functions in general have more negative oxide formation energy and thus have a stronger tendency to form oxides when two metals compete for forming metal-oxygen bonds.

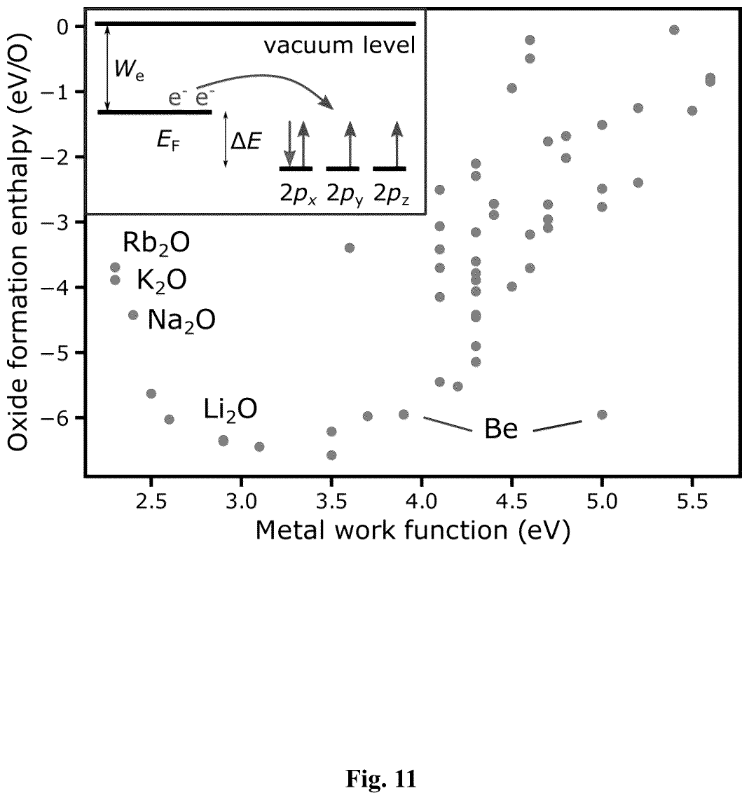

We examined this observation by considering one of the energy contributions to the formation of a metal oxide (ionic ones)—the transfer of electrons from the metal Fermi energy to the oxygen p orbitals (see the inset of FIG. 11). The idea behind is that when a metal oxidizes, electrons are transferred from Fermi energy of a metal to oxygen unfilled p orbitals, and the energy difference can largely represent the thermodynamic driving force for the oxidation reaction to happen. This could explain why metals with low work functions might be easier to oxidize.

To check how this hypothesis corresponds to the observed trends, we constructed a scatter plot of the enthalpies of formation of binary oxides against the work functions of the corresponding metals shown in FIG. 11. We assumed that the energy position of oxygen p-orbitals within oxides remains the same for all the oxides. Additionally, some metal can form oxides with different stoichiometries, and we include in our analysis only those that have nominal oxidation state of −2 for oxygen (no peroxides, for example). This criterion ensures that oxygen captures two electrons only from metals. Formation enthalpies are normalized by the number of oxygen atoms in the chemical formulas.

FIG. 11 shows a reasonable trend between the oxide formation enthalpy per oxygen and work functions of corresponding metals. As expected, the trend is qualitative as there is much more to the oxide formation energies than just the electron transfer. The only strong outliers are alkali oxides Na₂O, K₂O, and Rb₂O out of a total of 57 oxides considered. Nonetheless, the trend from FIG. 11 provides a simple and intuitive way to understand our results and a quick way to estimate whether a given metal will oxidize in contact with an oxide formed by a different metal by comparing the work functions of the two metals. Namely, if the metal in question has a lower work function than the one in an oxide, the formation of the oxide at the interface rather than a stable coexistence with the metal in question is likely. In addition, this chemical intuition is consistent with the known linear correlation between electronegativity and work function for metals.

Lastly, we collected metal work functions from the CRC Handbook of Chemistry and Physics, and these numbers are known to be sensitive to surface orientations. We used the average values if no values exist for polycrystalline samples. Technetium has no experimentally measured values but has an estimated value at 4.82 eV. We also note that a very different value from 5.0 eV for beryllium (3.9 eV) was also reported.

### CONCLUSION

In summary, we applied the computational (first-principles) thermodynamics to estimate the thermochemical stability of metal/semiconductor interfaces for β-Ga₂O₃, rutile GeO₂, and wurtzite GaN. In general, for the two wide-band-gap oxides, we find that only noble metals can form stable contacts under reasonable oxygen partial pressure (>10⁻¹⁰ atm). These metals tend to form Schottky barriers with n-type doped β-Ga₂O₃ and rutile GeO₂ based on the Schottky-Mott rule. Hence, degenerate doping of active materials, if possible, should be used to lower the interfacial resistance and form effective Ohmic contacts. Alternatively, SnO₂ is predicted to stably coexist with both β-Ga₂O₃ and rutile GeO₂ at wide ranges of temperatures and oxygen partial pressures, which could provide another solution to the Ohmic contact problem for ultrawide-gap oxides. In comparison, for GaN, consistent with the general knowledge that N₂ molecules are chemically relatively inert, more metals are predicted to form stable contacts without the involvement of oxygen. The commonly used Ohmic contact metal Ti is predicted to react with GaN, but the products are all conductive nitrides. The same is true for Ta, Mo, and to some extent Zr. Beyond finding stable contacts, generated phase diagrams are also useful for identifying appropriate synthesis condition of ternary compounds.

### Materials and Methods

Predicting Thermochemistry and Phase Equilibria. We use the grand canonical ensemble formalism to evaluate the driving forces for interface chemistry and predict phase equilibria at the semiconductor/contact interface. This is necessary when dealing with elemental constituents, such as O and N, that are normally in the gaseous state. Briefly, for a system in equilibrium with its environment and elemental chemical reservoirs, its state can be described in terms of chemical potentials of constituent elements, temperature, and pressure. Any choice of the pressure and temperature will determine the values of all elemental chemical potentials and the Gibbs free energies of all compounds within a given chemical system. The state of the system will be the one that minimizes the total Gibbs free energy, including all relevant phases. This minimal condition can be elegantly formulated using the following system of inequalities:

$$\begin{matrix}{{\sum }_{j = 1}}^{C} {n}_{ij} Δ {μ}_{i} ( T , p ) \leq {G}_{i}^{( i )} ( T , p ) , & i = 1 , … , P\end{matrix} \qquad [ Eq . 1 ]$$

where j counts different components (or elements, totaling to C), i counts all possible phases the could form (totaling to P), nᵢⱼ are the number of atoms of the component j in the chemical formula of phase i, Δμⱼ(T,p) are the elemental chemical potentials expressed relative to the chemical potential of the same component in its standard state (μi) at the respective temperature (T) and pressure (p), and ΔG⁽ⁱ⁾(T,p) are the Gibbs free energies of formation of each phase expressed per one formula unit. It is important to note that all pure elemental phases are also included in these inequalities. Namely, for each element there will be only one n=1 with all others zero, and by definition ΔG_{f}=0 for each pure elemental phase, implying Δμj≤0. Also, while strict inequalities can all be fulfilled simultaneously, not all equalities can exist simultaneously. The equalities that are fulfilled for a given set of Δμj≤0 values determine which phases are stable under those conditions. If only one equality is satisfied for a given set of Δμj values, this implies the thermodynamic stability of the corresponding compound and the instability of all others for which ΣnijΔμj<ΔG⁽ⁱ⁾. Two or more equalities existing simultaneously imply coexistence of the corresponding phases at those conditions.

The set of inequalities from Eq. 1 defines a convex hyperpolygon in the chemical potential (hyper)space whose faces represent the single-phase regions and vertices and edges represent the phase coexistence. To solve the inequalities (Eq. 2), we use the double description method by Motzkin et al. implemented as the C library cddlib. To include as many states as possible, we utilize existing computational databases, specifically NRELMatDb and Materials Project which account for most of the experimentally realized compounds, along with hypothetical ones. Additionally, in our considerations, we assume low-pressure (p≈0) conditions for all solid phases. Pressure dependencies are included in the chemical potentials of the gaseous species, which depend more strongly on the corresponding partial pressures. The considered gas partial pressures are all equal to or below 1 atm, which remains practically zero for solid phases. The dependencies of the elemental chemical potentials of gaseous species on the respective partial pressures are approximated using the ideal gas law.

To illustrate our approach, let us consider the Ga—Ti—O chemical system which is of relevance for making Ohmic contacts to P—Ga₂O₃. When hcp Ti is deposited on β-Ga₂O₃, the stability of the Ti/β-Ga₂O₃ interface at given conditions depends on whether a combination Ti+Ga₂O₃ has the lowest Gibbs free energy among all the possible compounds that are made of Ga, Ti, and O. To answer this question, we consider all possible compounds (phases) within this chemical space including not only Ga₂O₃ and TiO₂ but also the ternary compound Ga₄TiO₈ and the Ti—O Magnelli phases Ti₉O₁₇, Ti₈O₁₅, Ti₇O₁₃, Ti₆O₁₁, Ti₅O₉, Ti₄O₇, Ti₃O₅, Ti₂O₃,Ti₄O₅, TiO, Ti₂O, Ti₃O, and Ti₆O. Results are summarized in the form of the p_{O}2-temperature phase diagram shown in FIG. 12.

Each region is labeled by a single phase or two phases that can coexist. Labels in parentheses refer to two possible options for phase coexistence. For example, in the top left part of the diagram the Ga₄TiO₈ ternary compound could stably coexist at those conditions with either TiO₂ or Ga₂O₃ (not both simultaneously) depending on the Δμ_{Ti} and Δμ_{Ga}, or, in other words, the excess of one or the other relative to the perfect Ga:Ti=4:1 ratio. In the case of a perfect 4:1 only the Ga₄TiO₈ ternary bond would form. Lines in FIG. 12 represent the three-phase coexistence.

It is evident from this plot that β-Ga₂O₃ is never in equilibrium with elemental Ti, always with one of its oxides or the ternary compound, implying that the Ohmic contact typical for β-Ga₂O₃ either has a secondary oxide layer that forms spontaneously or is in the metastable state that is likely going to evolve with time. Experimental evidence supporting this prediction can be found in our recent work, where it was shown that Ti oxidizes almost fully when in contact with β-Ga₂O₃ leading to the degradation of the device performance over time upon exposure to elevated temperatures. What this type of analysis requires are the ΔG_{f} values and their temperature dependence for all phases, including the elemental chemical potentials. How ΔG_{f} is obtained in our approach is discussed next.

ΔG_{f} of Inorganic Compounds. The Gibbs free energy (molar) of a given compound is a function of temperature and pressure. Most computational materials databases, however, only report low-temperature and p=0 enthalpies of formation (ΔH_{f}), which can serve as the approximation for the low-temperature and low-pressure ΔG_{f} values. In addition, common approximations to density functional theory (DFT), like the GGA for example, typically result in large differences between the computed ΔH_{f} values of inorganic compounds and the measured ones (on average by ˜250 meV/atom⁷). To address this limitation of DFT, we primarily use the ΔH_{f} values from NRELMatDB calculated using the fitted elemental-phase reference energies (FERE) approach, which allows improved predictions of the compound formation enthalpies (≈50 meV/atom). Similarly, the data from Materials Project employs an alternative way of correcting for the DFT deficiencies, which combines DFT and DFT+U.

For the temperature dependence of the Gibbs free energies, we utilize the model description of the phonon contributions to the ΔG_{f}. which was shown to result in the temperature-dependent ΔG_{f} values with an accuracy of ˜50 meV/atom which is largely inherited from the ΔH_{f} values that are used as the starting point.¹ The model equation is:

$${G}_{i}^{( i )} = Δ {H}_{i}^{( i )} + δ {G}^{( i )} ( T ) - {{\sum }_{j}}^{N} {n}_{i , j} {μ}_{i , exp} ( T ) \qquad ( Eq . 2 )$$

where ΔH⁽ⁱ⁾ represents the enthalpy of formation of the phase i at standard conditions (from FERE), δG⁽ⁱ⁾(T) is the term that introduces the temperature dependence modeled as before n_{i,j} are the stoichiometric weights of elements, and μi,exp(T) are the temperature-dependent experimental chemical potentials of elemental constituents in their reference phases that are taken from the FactSage package. When calculating ΔG⁽ⁱ⁾(T), the most stable (lowest Gibbs free energy) phases are used for elements if phase transitions occur with increasing temperature. The δG⁽ⁱ⁾(T) (in eV/atom) is defined by:

$$( Eq . 3 )$$

$$δ {G}^{( i )} ( T ) = ( - 2.48 \times {10}^{- 4} In ( V ) - 8.94 \times {10}^{- δ} \frac{m}{V} ) T + 0.181 ln ( T ) - 0.882$$

where V is the volume of the compound in A/atom and m is the reduced atomic mass (in amu).

For the two gaseous molecules, O2 and N2, considered in the analysis, we modeled the dependence of their relative chemical potentials (Δμi) to the temperature T and gas partial pressure using the ideal gas law, ΔμO=1/2kBT ln(pOd2) and ΔμN=1/2kBT ln(pNd2), for O2 and N2 referenced to the experimental value value μi,exp(T) at standard pressure (1 atm). As a result, we can construct the pOd2-T and pNd2-T phase diagrams as the one in FIG. 12.

Lastly, we also estimate the uncertainty of the pOd2-T phase diagram predictions. For the same amount of uncertainty in chemical potential of O or N, the ideal gas model indicates that the uncertainty in partial pressure strongly depends on temperature. For instance, an overestimate of oxygen chemical potential by 50 meV will lead to about 50 times larger oxygen partial pressure at 300 K, but it only gives rise to about 4 times larger oxygen partial pressure at 900 K. Therefore, even though the uncertainty in chemical potential of gaseous elements is system-dependent, we can generally expect lower uncertainty in predicted partial pressure at higher temperature. While these uncertainties may seem large, which is a consequence of the exponential dependency on chemical potential, the order of magnitude of the gas partial pressures is robustly predicted at typical synthesis temperatures. The results presented here, hence, need to be interpreted as predictive in the order magnitude of partial pressure at any given temperature.

The present invention may be further understood by the following non-limiting examples:

Example 1. A device comprising:
a p-type layer;
an n-type Ga₂O₃ layer; and
an XGa₂O₄ layer positioned between the p-type transition metal oxide layer and the n-type Ga₂O₃ layer, wherein X is a transition metal.

Example 2. The device of example 1, wherein the p-type transition metal oxide layer comprises NiO.

Example 3. The device of example 1 or 2, wherein X is Ni.

Example 4. The device of any of examples 1-3, wherein the n-type Ga₂O₃ layer is coincidence site lattice matched along the (100) direction of the Ga₂O₃ layer with the p-type transition metal oxide layer along the (010) direction.

Example 5. The device of any of examples 1-4, wherein the n-type Ga₂O₃ layer is coincidence site lattice matched along the (010) direction of the Ga₂O₃ layer with the p-type transition metal oxide layer along the (100) direction.

Example 6. The device of any of examples 1-5 wherein the XGa₂O₄ layer has a spinel crystal structure.

Example 7. The device of any of examples 1-6, wherein the XGa₂O₄ layer is p-type.

Example 8. The device of any of examples 1-7, wherein the device has improved thermodynamic stability at temperatures greater than 250° C.

Example 9. The device of any of examples 1-8, wherein the device is a p-n heterojunction semiconductor.

Example 10. The device of any of examples 1-9, wherein the XGa₂O₄ layer has a height selected from the range of 1 nm to 10 nm.

Example 11. The device of any of examples 1-10, wherein the n-type Ga₂O₃ layer is p-Ga₂O₃.

Example 12. The device of any of examples 1-11, wherein the p-type layer comprises a transition metal oxide.

Example 13. A device comprising:
a p-type NiO layer;
an n-type Ga₂O₃ layer; and
an NiGa₂O₄ layer positioned between the p-type transition metal oxide layer and the n-type Ga₂O₃ layer and having a spinel crystal structure.

Example 14. The device of example 13, wherein the n-type Ga₂O₃ layer is coincidence site lattice matched along the (100) direction of the Ga₂O₃ layer with the p-type NiO layer along the (010) direction.

Example 15. The device of example 13 or 14, wherein the n-type Ga₂O₃ layer is coincidence site lattice matched along the (010) direction of the Ga₂O₃ layer with the p-type NiO layer along the (100) direction.

Example 16. The device of any of examples 13-15, further comprising a Ti layer proximate to the n-type Ga₂O₃ layer and a Ni layer proximate to the p-type NiO layer.

Example 17. The device of example 16, further comprising one or more Au layers proximate to the Ti layer, the Ni layer, or both.

The terms and expressions which have been employed herein are used as terms of description and not of limitation, and there is no intention in the use of such terms and expressions of excluding any equivalents of the features shown and described or portions thereof, but it is recognized that various modifications are possible within the scope of the invention claimed. Thus, it should be understood that although the present invention has been specifically disclosed by preferred embodiments, exemplary embodiments and optional features, modification and variation of the concepts herein disclosed may be resorted to by those skilled in the art, and that such modifications and variations are considered to be within the scope of this invention as defined by the appended claims. The specific embodiments provided herein are examples of useful embodiments of the present invention and it will be apparent to one skilled in the art that the present invention may be carried out using a large number of variations of the devices, device components, methods steps set forth in the present description. As will be obvious to one of skill in the art, methods and devices useful for the present methods can include a large number of optional composition and processing elements and steps.

As used herein and in the appended claims, the singular forms “a”, “an”, and “the” include plural reference unless the context clearly dictates otherwise. Thus, for example, reference to “a cell” includes a plurality of such cells and equivalents thereof known to those skilled in the art. As well, the terms “a” (or “an”), “one or more” and “at least one” can be used interchangeably herein. It is also to be noted that the terms “comprising”, “including”, and “having” can be used interchangeably. The expression “of any of claims XX-YY” (wherein XX and YY refer to claim numbers) is intended to provide a multiple dependent claim in the alternative form, and in some embodiments is interchangeable with the expression “as in any one of claims XX-YY.”

When a group of substituents is disclosed herein, it is understood that all individual members of that group and all subgroups, are disclosed separately. When a Markush group or other grouping is used herein, all individual members of the group and all combinations and subcombinations possible of the group are intended to be individually included in the disclosure. For example, when a device is set forth disclosing a range of materials, device components, and/or device configurations, the description is intended to include specific reference of each combination and/or variation corresponding to the disclosed range.

Every formulation or combination of components described or exemplified herein can be used to practice the invention, unless otherwise stated.

Whenever a range is given in the specification, for example, a density range, a number range, a temperature range, a time range, or a composition or concentration range, all intermediate ranges and subranges, as well as all individual values included in the ranges given are intended to be included in the disclosure. It will be understood that any subranges or individual values in a range or subrange that are included in the description herein can be excluded from the claims herein.

All patents and publications mentioned in the specification are indicative of the levels of skill of those skilled in the art to which the invention pertains. References cited herein are incorporated by reference herein in their entirety to indicate the state of the art as of their publication or filing date and it is intended that this information can be employed herein, if needed, to exclude specific embodiments that are in the prior art. For example, when composition of matter is claimed, it should be understood that compounds known and available in the art prior to Applicant's invention, including compounds for which an enabling disclosure is provided in the references cited herein, are not intended to be included in the composition of matter claims herein.

As used herein, “comprising” is synonymous with “including,” “containing,” or “characterized by,” and is inclusive or open-ended and does not exclude additional, unrecited elements or method steps. As used herein, “consisting of” excludes any element, step, or ingredient not specified in the claim element. As used herein, “consisting essentially of” does not exclude materials or steps that do not materially affect the basic and novel characteristics of the claim. In each instance herein any of the terms “comprising”, “consisting essentially of” and “consisting of” may be replaced with either of the other two terms. The invention illustratively described herein suitably may be practiced in the absence of any element or elements, limitation or limitations which is not specifically disclosed herein.

All art-known functional equivalents, of any such materials and methods are intended to be included in this invention. The terms and expressions which have been employed are used as terms of description and not of limitation, and there is no intention that in the use of such terms and expressions of excluding any equivalents of the features shown and described or portions thereof, but it is recognized that various modifications are possible within the scope of the invention claimed. Thus, it should be understood that although the present invention has been specifically disclosed by preferred embodiments and optional features, modification and variation of the concepts herein disclosed may be resorted to by those skilled in the art, and that such modifications and variations are considered to be within the scope of this invention as defined by the appended claims.

What is claimed is:

1. A device comprising:
a p-type layer;
an n-type Ga₂O₃ layer; and
an XGa₂O₄ layer positioned between the p-type transition metal oxide layer and the n-type Ga₂O₃ layer, wherein X is a transition metal.

2. The device of claim 1, wherein the p-type transition metal oxide layer comprises NiO.

3. The device of claim 1, wherein X is Ni.

4. The device of claim 1, wherein the n-type Ga₂O₃ layer is coincidence site lattice matched along the (100) direction of the Ga₂O₃ layer with the p-type transition metal oxide layer along the (010) direction.

5. The device of claim 1, wherein the n-type Ga₂O₃ layer is coincidence site lattice matched along the (010) direction of the Ga₂O₃ layer with the p-type transition metal oxide layer along the (100) direction.

6. The device of claim 1, wherein the XGa₂O₄ layer has a spinel crystal structure.

7. The device of claim 1, wherein the XGa₂O₄ layer is p-type.

8. The device of claim 1, wherein the device has improved thermodynamic stability at temperatures greater than 250° C.

9. The device of claim 1, wherein the device is a p-n heterojunction semiconductor.

10. The device of claim 1, wherein the XGa₂O₄ layer has a height selected from the range of 1 nm to 10 nm.

11. The device of claim 1, wherein the n-type Ga₂O₃ layer is β-Ga₂O₃.

12. The device of claim 1, wherein the p-type layer comprises a transition metal oxide.

13. A device comprising:
a p-type NiO layer;
an n-type Ga₂O₃ layer; and
an NiGa₂O₄ layer positioned between the p-type transition metal oxide layer and the n-type Ga₂O₃ layer and having a spinel crystal structure.

14. The device of claim 13, wherein the n-type Ga₂O₃ layer is coincidence site lattice matched along the (100) direction of the Ga₂O₃ layer with the p-type NiO layer along the (010) direction.

15. The device of claim 13, wherein the n-type Ga₂O₃ layer is coincidence site lattice matched along the (010) direction of the Ga₂O₃ layer with the p-type NiO layer along the (100) direction.

16. The device of claim 13, further comprising a Ti layer proximate to the n-type Ga₂O₃ layer and a Ni layer proximate to the p-type NiO layer.

17. The device of claim 16, further comprising one or more Au layers proximate to the Ti layer, the Ni layer, or both.
